(19) United States
(12) Patent Application Publication
(10) Pub. No.: US 2007/0171703 A1
(43) Pub. Date: Jul. 26, 2007

(54) CURRENT SOURCE OF MAGNETIC RANDOM ACCESS MEMORY

(75) Inventors: Rei-Fu Huang, Hsinchu (TW); Young-Shying Chen, Hsinchu (TW); Chien-Chung Hung, Hsinchu (TW); Yuan-Jen Lee, Hsinchu (TW); Ming-Jer Kao, Hsinchu (TW)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(73) Assignee: INDUSTRIAL TECHNOLOGY RESEARCH INSTITUTE, Hsinchu (TW)

(21) Appl. No.: 11/558,297

(22) Filed: Nov. 9, 2006

(30) Foreign Application Priority Data
Jan. 20, 2006 (TW) 095102310

(51) Int. Cl. G11C 11/00

(52) U.S. Cl. 365/158

(57) ABSTRACT

A current source for magnetic random access memory (MRAM) is provided, including a band-gap reference circuit, a first stage buffer, and a plurality of second stage buffers. The band-gap reference circuit provides an output reference voltage which is locked by the first stage buffer. The plurality of second stage buffers generate a stable voltage in response to the locked voltage, so as to provide a current for the conducting wire after being converted, such that magnetic memory cell changes its memory state in response to the current. The current source may reduce the discharge time under the operation of biphase current, so as to raise the operating speed. Further, the circuit area of the current source for the MRAM is also reduced. The operation of multiple write wires may be provided simultaneously to achieve parallel write.

### CROSS-REFERENCE TO RELATED APPLICATIONS

This non-provisional application claims priority under 35 U.S.C. §119(a) on Patent Application No(s). 095102310 filed in Taiwan, R.O.C. on Jan. 20, 2006, the entire contents of which are hereby incorporated by reference.

### BACKGROUND OF THE INVENTION

1. Field of Invention

The present invention relates to the write current provided by a current source particularly applied to a magnetic random access memory.

2. Related Art

Magnetic random access memory (MRAM) mainly uses the characteristic of electron spin to record signals “0” and “1” according to the magnetic resistance features generated by different magnetization directions of the free layer in the magnetic structure. MRAM has the non-volatile characteristic of flash memory, the high density potential of dynamic random access memory (DRAM), and the quick access advantage of static random access memory (SRAM). When data are written into the MRAM, a general method is to use two current lines: a bit line and a write word line to induce cells intersected by magnetic fields and changing the resistance values of the cells by changing the magnetization direction of the ferromagnetic free layer. When the MRAM reads memory data, current sources must be provided to flow into the selected magnetic memory cells, thus reading different resistance values of the cells to determine the digital values of the data.

However, when MRAM is developed toward high density, the dimension of the magnetic memory cells must be reduced, such that the switching field of the sensing layer is enlarged. Thus, the required current increases and also it is a great challenge in circuit design. When the magnetic memory cells are fabricated, due to the difficulty in controlling the process conditions, the shape of each bit in the memory may be different. Therefore, the size of the write magnetic field of each bit may be different, resulting in poor write selectivity of the MRAM, and increasing the difficulty in the introduction of mass production of the memory.

In the conventional operation of the MRAM, current mirror is usually adopted. As shown in FIG. 1, the current mirror is constituted by transistors 13, 14 and transistors 15, 16, to replicate the current of the current sources 11, 12, thereby increasing the output current to meet the requirement of the MRAM for a large write current.

However, to withstand such a large current, the area and switching speed of the transistor are limited. For example, in the conventional design of a current mirror, to avoid damaging the circuit by simultaneously conducting the current sources at both ends, a discharge time is needed between the switching of the two current sources. The method takes a long operating time, and is not suitable for the operation of a biphase current. Further, the operation of a large current may result in an increase in the area of the transistor, thereby increasing the volume of the device.

### SUMMARY OF THE INVENTION

According to the aspect of the invention, the writing current of MRAM is provided by a current source, which includes a band-gap reference circuit for providing a reference voltage; a first stage buffer, connected to the band-gap reference circuit, for locking the reference voltage output by the band-gap reference circuit; a plurality of second stage buffers, for generating a stable voltage value in response to the voltage, so as to provide a current for the conducting wire after being converted; and a magnetic memory cell with its memory state changed in response to the current.

Accordingly, it is an object of the present invention to reduce the discharge time under the operation of biphase current for raising the operating speed.

Another object of the present invention is to reduce the circuit area of the current source for the MRAM.

A still further object of the present invention is to provide the operation of multiple write wires simultaneously to achieve parallel write.

The above illustration of the content of the invention and the following illustration of the embodiments are intended to demonstrate and explain the spirit and principle of the present invention, and provide further explanation for the claims of the invention.

Further scope of applicability of the present invention will become apparent from the detailed description given hereinafter. However, it must be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and which thus is not limitative of the present invention, and wherein:

FIG. 1 is a circuit diagram of the current source for the MRAM provided by the prior art;

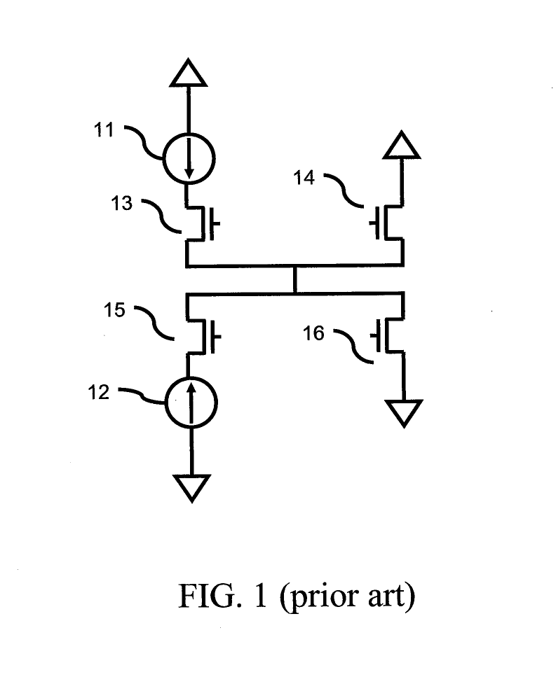

FIG. 2 is an architectural view of the current source for the MRAM provided by the present invention;

FIG. 3 is a circuit diagram of one embodiment of the band-gap reference circuit in the current source for the MRAM provided by the present invention;

FIG. 4 is a circuit diagram of another embodiment of the band-gap reference circuit in the current source for the MRAM provided by the present invention;

FIG. 5 is a diagram of the operating principle of the current source for the MRAM provided by the present invention; and

FIG. 6 is a diagram of one embodiment of the memory adapted to the current source for the MRAM provided by the present invention.

### DETAILED DESCRIPTION OF THE INVENTION

The detailed features and advantages of the present invention are discussed in detail in the following embodiments. Anybody skilled in the related arts can easily understand and implement the content of the technology of the invention. Furthermore, the relative objects and advantages of the present invention are apparent to those skilled in the related arts according to the content disclosed in the specification, claims, and drawings.

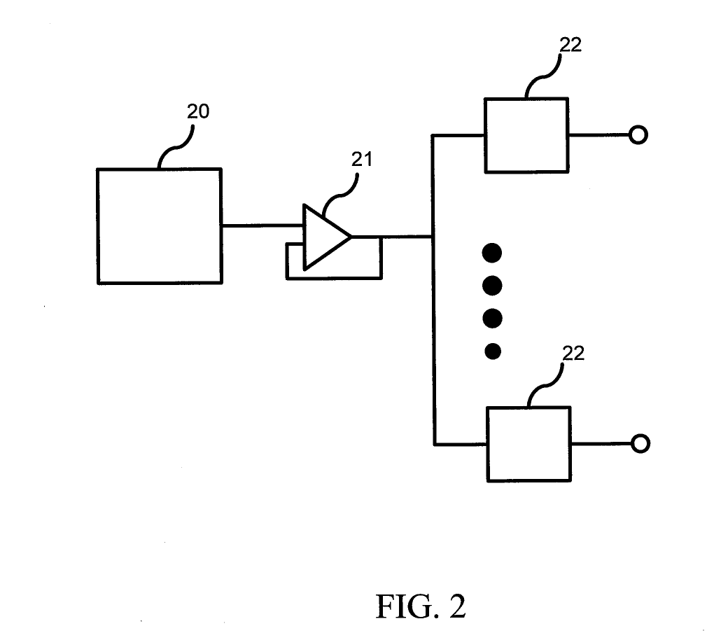

As shown in FIG. 2, it is an architectural view of the current source applied to the MRAM provided by the present invention. The current source includes a band-gap reference circuit 20, a first stage buffer 21, and a plurality of second stage buffers 22 and switches.

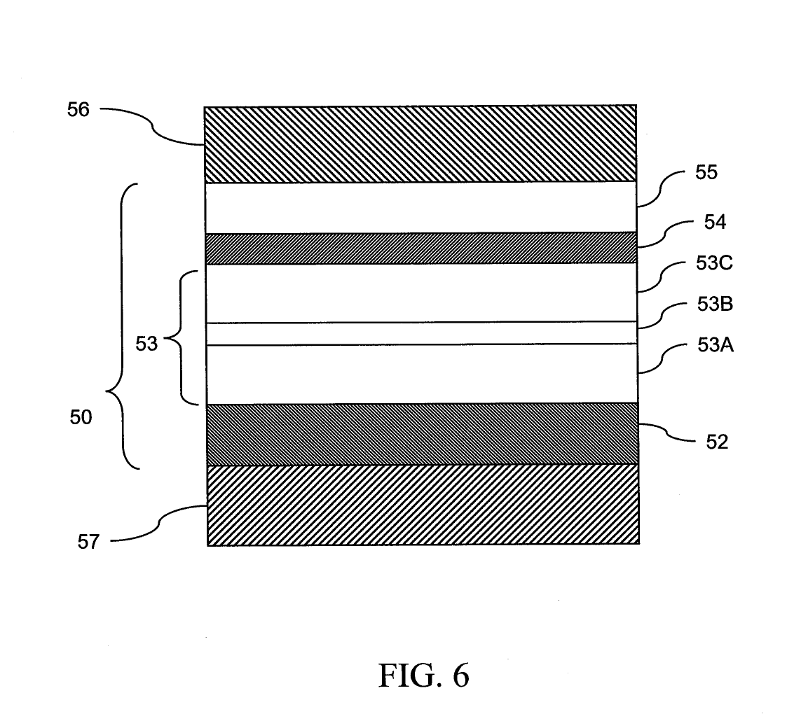

The band-gap reference circuit 20 is used to provide a reference voltage. The first stage buffer 21 is connected to the band-gap reference circuit 20 for locking the reference voltage provided by the band-gap reference circuit 20. The second stage buffer 22 is used to generate a stable voltage in response to the voltage, so as to provide a current for the conducting wire after being converted, such that the MRAM changes its memory state in response to the current. The detailed description of an embodiment of the MRAM adapted to the present invention is provided later with reference to FIG. 6.

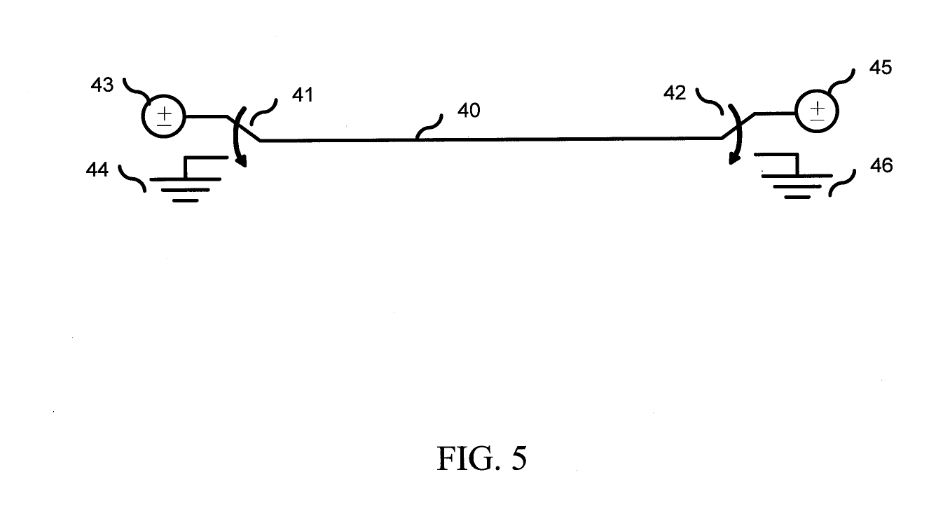

In an exemplary example, the first stage buffer 21 can be a unit-gain buffer amplifier. As the second stage buffer 22 is connected to a word line or bit line controlling the memory device, the current output by the second stage buffer 22 needs adequate driving power to be converted to output enough current for turning the magnetic moment of the free layer in the MRAM. Two electrically connected switches are disposed in the second stage buffer 22, wherein one end of each switch is grounded while the other end is connected to a constant voltage source. The detailed description of this part will be given later with reference to FIG. 5.

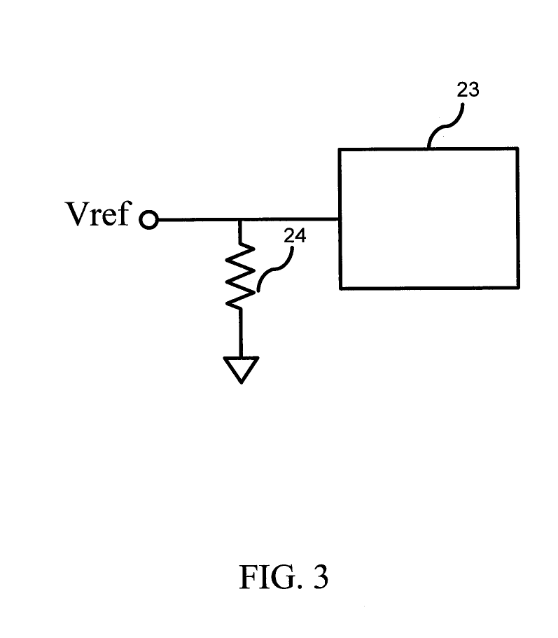

As shown in FIG. 3, it is a circuit diagram of the embodiment of the band-gap reference circuit 20. The band-gap reference circuit 20 is constituted by an output reference current circuit 23 and a voltage regulator 24. The voltage regulator 24 can be, for example, a resistor. The output reference current circuit 23 is constituted by an amplifier and other circuits, wherein the amplifier can be a low voltage amplifier. The voltage regulator 24 is used to regulate the output of the reference voltage circuit, so as to obtain a desired voltage value.

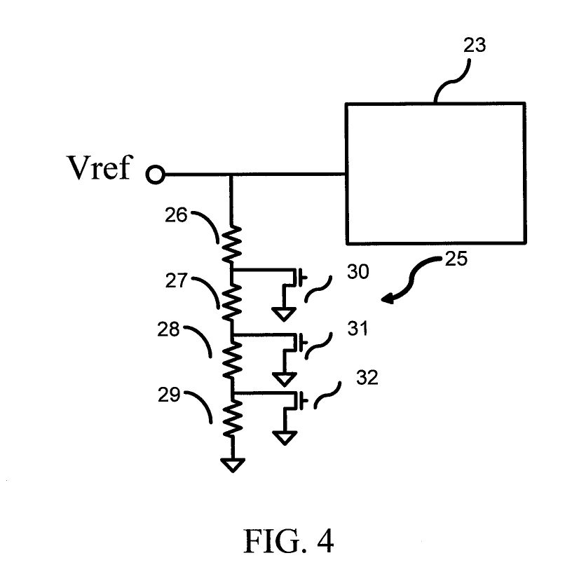

As shown in FIG. 4, it is a circuit diagram of another embodiment of the band-gap reference circuit 20. The band-gap reference circuit 20 is also constituted by an output reference current circuit 23 and a voltage regulator 25. In view of the problem that the resistances of the bit line and the write word line are not uniformly distributed, the voltage regulator 25 must regulate the band-gap reference voltage value output by the output reference current circuit 23. The voltage regulator 25 is constituted by resistors 26, 27, 28, 29 and transistors 30, 31, 32, so as to regulate the output appropriately according to the resistance distribution of the bit line and the write word line. The amplifier inside the output reference current circuit 23 can also be a low voltage amplifier.

The resistors 26, 27, 28, 29 are connected to each other in series. The unconnected end of the resistor 26 is connected to the output reference current circuit 23. The unconnected end of the resistor 29 is connected to the ground end. The sources of the transistors 30, 31, 32 are connected between each two adjacent resistors, for example, the source of the transistor 30 is connected between the resistors 26 and 27. The series resistance of the resistors 26, 27, 28, 29 is controlled by the on and off of the transistors 30, 31, 32, so as to regulate the output reference voltage of the band-gap reference circuit 20.

As shown in FIG. 5, it illustrates the operating principle of the current source provided by the present invention. The architecture shown in FIG. 5 is simplified for illustration. In practice, the switch can be devices with the same characteristic as a switch, for example a diode or a transistor (such as metal-oxide-semiconductor field effect transistors). To replace the conventional design of a current source, the present invention uses the parasitic resistance of the line and the voltage difference between the two ends to provide a stable biphase current to operate the circuit. Switches 41, 42 as shown in FIG. 5 are disposed in the second stage buffer circuit and are electrically connected via a conducting wire 40. Ground ends 44, 46 and constant voltage sources 43, 45 are respectively disposed at both ends of the second stage buffer circuit, wherein the voltage in the constant voltage sources 43, 45 is the product of the parasitic resistance of the conducting wire and the required drive current.

As the switches 41, 42 shown in FIG. 5 are disposed in the second stage buffer, only the transistors connected behind the switches have to withstand large current. Therefore, the number of transistors requiring a large area can be reduced, and thus the area of the whole current source can be reduced by the architecture shown in FIG. 5.

Further, as the driving power of the current comes from the second stage buffer, and the word line and bit line of each unit are driven by an individual second stage buffer, multiple groups of the word line and bit line can be simultaneously driven in parallel. Therefore, in the architecture in FIG. 2, the word line and bit line of each unit are both controlled by the output of an individual second stage buffer, so the output current value will not be affected by load effect.

When switching the biphase current source used in the prior art, the current at both ends may conflict with each other if the current sources are on and off at the same time. With the architecture in FIG. 5, when the signals controlling the current sources overlap, the conflict will not occur even if the current sources are on and off at the same time, and only the current returns to zero. Therefore, extra discharge time is not necessary, thereby improving overall operating time and speed.

As for the current source used in the prior art, to avoid damaging the device by turning on the current sources at both ends simultaneously, a discharge time must be preset between switches for successfully switching different current sources. However, according to the architecture shown in FIG. 5, as voltages are switched at both ends, extra discharge time is not necessary, so it has flexible controlling conditions.

An embodiment of the MRAM adapted to the present invention is illustrated in detail as follows with reference to FIG. 6.

The MRAM is constituted by a magnetic memory cell 50, an upper electrode 56, and a lower electrode 57. The magnetic memory cell 50 is constituted by a magnetic multiple-layered film, for example, a magnetic tunnel junction (MTJ). The upper electrode 56 and the lower electrode 57 can be formed by conductive materials for conducting current. In the figure, the upper electrode 56 is located on the top of the magnetic memory cell 50, and the lower electrode 57 is located at the bottom of the magnetic memory cell 50. It will be apparent to those of ordinary skill in the art that the upper electrode 56 and the lower electrode 57 can be respectively connected to the bit line and the read transistor, to facilitate reading and writing data.

In the figure, the magnetic memory cell 50 has a multi-layered structure of an antiferromagnetic layer 52, an upper fixed layer 53A, an intermediate separation layer 53B, a lower fixed layer 53C, a tunneling insulation layer 54, and a free layer 55. For example, the antiferromagnetic layer 52 can be fabricated by PtMn or IrMn. The fixed layer 53 can be a ferromagnetic layer with more than one layer or an artificial antiferromagnetic layer of a three-layer structure made of CoFe/Ru/CoFe or CoFeB/Ru/CoFeB. The tunneling insulation layer 54 can be made of AlOx or MgO. The free layer 55 can be a ferromagnetic layer with more than one layer or an artificial antiferromagnetic layer of a three-layer structure made of NiFe/CoFe or CoFeB, wherein the artificial antiferromagnetic free layer can be made of CoFe/Ru/CoFe, NiFe/Ru/NiFe or CoFeB/Ru/CoFeB. The above listed materials are for illustration only, it will be apparent to those of ordinary skill in the art that other materials capable of achieving the same effect can also be adopted.

As for the write mechanism of the free layer 55 in the magnetic memory cell 50, it will be apparent to those of ordinary skill in the art that cross selection write mode or toggle mode write mode can be used.

The MRAM memorizes data mainly by the fixed layer 53, the tunneling insulation layer 54, and the free layer 55. The state of data is determined by the parallel and anti-parallel arrangements of the magnetic moment in the free layer 55 and the upper fixed layer 53A.

When the two magnetic moments are in parallel, the resistance of the NRAM is the lowest, so a large current is induced to pass through the MRAM when a bias voltage is applied, and this state is defined as “0”. When the two magnetic moments are in anti-parallel, the resistance of the MRAM is the highest, so a small current is induced to pass through the MRAM when a bias voltage is applied, and the state is defined as “1”. It will be apparent to those of ordinary skill in the art that the definitions can be opposite or random, and this example is used for illustration only.

The above-mentioned architecture of the MRAM is only used for exemplarily illustrating the architecture of the memory adapted to the present invention, instead of limiting the memory adapted to the present invention. The current source for the MRAM provided by the present invention can eliminate the discharge time under the biphase current operation, so as to raise the operating speed. Further, the circuit area of the current source for the MRAM can be reduced. The operation of multiple write wires can be provided simultaneously to achieve parallel write.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A current source of magnetic random access memory (MRAM), which comprising:
a band-gap reference circuit, for providing a reference voltage;
a first stage buffer, connected to the band-gap reference circuit, for locking the reference voltage output by the band-gap reference circuit; and
a plurality of second stage buffers, for generating a stable voltage in response to the locked reference voltage, so as to provide a current for a conducting wire after being converted.

2. The current source as claimed in claim 1, wherein each second stage buffer comprises two electrically interconnected switches both controllably switched between a voltage source and a ground end.

3. The current source as claimed in claim 1, wherein the first stage buffer is a unit-gain buffer amplifier.

4. The current source as claimed in claim 1, wherein the band-gap reference circuit at least comprises:
a voltage regulator; and
an output reference current circuit, connected to the voltage regulator.

5. The current source as claimed in claim 4, wherein the output reference current circuit comprises an amplifier.

6. The current source as claimed in claim 4, wherein the voltage regulator is a resistor.

7. The current source as claimed in claim 1, wherein the band-gap reference circuit comprises:
a plurality of resistors connected in series;
a plurality of metal-oxide-semiconductor field effect transistors (MOSFET), wherein the source of each MOSFET is connected between each two adjacent resistors; and
an output reference current circuit, connected to an end of the plurality of resistors connected in series.

8. The current source as claimed in claim 7, wherein the output reference current circuit comprises an amplifier.

9. A magnetic random access memory (MRAM), comprising:
a band-gap reference circuit, for providing a reference voltage;
a first stage buffer, connected to the band-gap reference circuit, for locking the reference voltage output by the band-gap reference circuit;
a plurality of second stage buffers, for generating a stable voltage in response to the locked reference voltage, so as to provide a current for a conducting wire after being converted; and
a magnetic memory cell with its memory state changed in response to the current.

10. The MRAM as claimed in claim 9, wherein each second stage buffer comprises two electrically interconnected switches controllably switched between a voltage source and a ground end.

11. The MRAM as claimed in claim 9, wherein the first stage buffer is a unit-gain buffer amplifier.

12. The MRAM as claimed in claim 9, wherein the band-gap reference circuit at least comprises:
a voltage regulator; and
an output reference current circuit, connected to the voltage regulator.

13. The MRAM as claimed in claim 12, wherein the output reference current circuit comprises an amplifier.

14. The MRAM as claimed in claim 12, wherein the voltage regulator is a resistor.

15. The MRAM as claimed in claim 9, wherein the band-gap reference circuit comprises:
a plurality of resistors connected in series;
a plurality of MOSFETs, wherein the source of each MOSFET is connected between each two adjacent resistors; and
an output reference current circuit, connected to an end of the plurality of resistors connected in series.

16. The MRAM as claimed in claim 15, wherein the output reference current circuit comprises an amplifier.
